(19) United States
(12) Patent Application Publication
(10) Pub. No.: US 2026/0323855 A1
(43) Pub. Date: Oct. 15, 2026

(54) DISPLAY APPARATUS

(71) Applicant: TCL CHINA STAR OPTOELECTRONICS TECHNOLOGY CO., LTD., Shenzhen (CN)

(72) Inventors: Bin ZHAO, Shenzhen (CN); Shi TANG, Shenzhen (CN); Hongyuan XU, Shenzhen (CN); Pengfei WEI, Shenzhen (CN); Xing LEI, Shenzhen (CN); Daobing HU, Shenzhen (CN); Guangmiao WAN, Shenzhen (CN); Bizhang ZHU, Shenzhen (CN)

(21) Appl. No.: 18/994,827

(22) PCT Filed: Dec. 15, 2023
(86) PCT No.: PCT/CN2023/139183

§ 371 Date: Jan. 15, 2025

(30) Foreign Application Priority Data
Dec. 7, 2023 (CN) 202311676243.2

(51) Int. Cl. H05K 5/30; H05K 5/02

(52) U.S. Cl. CPC H05K 5/30; H05K 5/0217

(57) ABSTRACT

A display apparatus includes at least two display devices, a supplementary light assembly, and a transition bracket. The supplementary light assembly includes light bar(s), first transmission member(s), transition board(s), and second transmission member(s) which are connected. The light bar(s) cover a splicing gap between any two of the display devices. The second transmission member(s) are disposed on a backside of two adjacent ones of the display devices, and the second transmission member(s) are detachably connected to the transition board(s) respectively.

### TECHNICAL FIELD

The present disclosure relates to the field of display technology, and in particular to a display apparatus.

### BACKGROUND

At present, display splicing technology is developing rapidly to realize the large-size display of the monitors. The splicing apparatuses formed by organic light-emitting diode display panels and micro-diode direct-view panels cannot be popularized on a large scale due to cost and reliability issues, so the splicing apparatuses of liquid crystal display panels are still the mainstream product on the market.

In an existing splicing apparatus, a light bar is usually provided between two display devices to eliminate the splicing gap between the two spliced display devices. Still, the light bar and the driver are not detachable, which makes it difficult to re-maintain and re-install this supplemental light structure.

### SUMMARY

The present disclosure provides a display apparatus to ameliorate the problem of difficulty in re-installing the supplemental light structure at the splicing gap between the existing spliced display devices.

To solve the above solution, the present disclosure provides the following technical solutions.

The present disclosure provides a display apparatus. The display apparatus includes at least two display devices, a transition bracket, and a supplementary light assembly.

A splicing gap is formed between two adjacent display devices of the at least two display devices.

The transition bracket is disposed on a backside of the two adjacent display devices, a portion of the transition bracket extends into the splicing gap, and the transition bracket is detachably connected to at least one of the two adjacent display devices.

The supplementary light assembly is detachably connected to the transition bracket. The supplementary light assembly includes one or more light bars, one or more first transmission members, one or more transition boards, and one or more second transmission members.

The one or more light bars are disposed on a light emitting side of the two adjacent display devices, and the one or more light bars cover the splicing gap.

The one or more first transmission members are disposed within the splicing gap, a first terminal of each first transmission member is electrically connected to a side of a corresponding one of the one or more light bars away from the light emitting side, and a second terminal of the first transmission member extends toward the backside of the two adjacent display devices and passes through the splicing gap.

The one or more transition boards are each disposed on a side of a corresponding one or more of the one or more first transmission members away from the one or more light bars, and a first terminal of the transition board is electrically connected to the second terminal of each of the corresponding one or more first transmission members.

The one or more second transmission members are each disposed on the backside of the two adjacent display devices, and a first terminal of the second transmission member is detachably connected to a second terminal of a corresponding one of the one or more transition boards.

The present disclosure further provides a display apparatus. The display apparatus includes at least two display devices, a transition bracket, and a supplementary light assembly.

A splicing gap is formed between two adjacent display devices of the at least two display devices.

The transition bracket is disposed on a backside of the two adjacent display devices, a portion of the transition bracket extends into the splicing gap, and the transition bracket is detachably connected to at least one of the two adjacent display devices.

The supplementary light assembly is detachably connected to the transition bracket. The supplementary light assembly includes one or more light bars, one or more first transmission members, one or more transition boards, one or more second transmission members, and a controller.

The one or more light bars are disposed on a light emitting side of the two adjacent display devices, and the one or more light bars cover the splicing gap.

The one or more first transmission members are disposed within the splicing gap, a first terminal of each first transmission member is electrically connected to a side of a corresponding one of the one or more light bars away from the light emitting side, and a second terminal of the first transmission member extends toward the backside of the two adjacent display devices and passes through the splicing gap.

The one or more transition boards are each disposed on a side of a corresponding one or more of the one or more first transmission members away from the one or more light bars, and a first terminal of the transition board is electrically connected to the second terminal of each of the corresponding one or more first transmission members.

The one or more second transmission members are each disposed on the backside of the two adjacent display devices, and a first terminal of the second transmission member is detachably connected to a second terminal of a corresponding one of the one or more transition boards.

The controller is fixed to the backside of one of the two adjacent display devices, and a second terminal of the second transmission member is electrically connected to the controller.

### BRIEF DESCRIPTION OF THE DRAWINGS

FIG. 1 is a diagram showing the structure of a display apparatus on a light emitting side in the present disclosure.

FIG. 2 is a diagram showing the structure of a display apparatus on a backside in the present disclosure.

FIG. 3 is the first diagram showing the structure of a supplementary light assembly in the display apparatus in the present disclosure.

FIG. 4 is the second diagram showing the structure of a supplementary light assembly in the display apparatus in the present disclosure.

FIG. 5 is a diagram showing the structure of a light bar on a side away from the light emitting side in the display apparatus in the present disclosure.

FIG. 6 is a diagram showing the structure of a transition bracket in the display apparatus in the present disclosure.

FIG. 7 is an enlarged view of region M in FIG. 6.

FIG. 8 is an enlarged view of region L in FIG. 6.

FIG. 9 is a top view of the structure of a transition bracket in the display apparatus in the present disclosure.

FIG. 10 is an enlarged view of region N in FIG. 9.

### DETAILED DESCRIPTION

The technical solutions in the embodiments of the present disclosure will be described clearly and completely in the following in conjunction with the drawings in the embodiments of the present disclosure, and it is apparent that the described embodiments are only part of embodiments of the present disclosure, and not all of the embodiments. Based on the embodiments in this disclosure, all other embodiments obtained by a person skilled in the art without making creative labour fall within the scope of protection of this disclosure. In addition, it should be understood that the specific embodiments described herein are used only to illustrate and explain the present disclosure and are not intended to limit the present disclosure. In the present disclosure, unless specified to the contrary, the used orientation words such as “up” and “down” usually refer to up and down in the actual use or working state of the apparatus, specifically the drawing directions in the drawings, and “inside” and “outside” are with respect to the contour of the apparatus.

In an existing splicing apparatus, a light bar is usually provided between two display devices to eliminate the splicing gap between the two spliced display devices, but the light bar and the driver are not detachable, which makes it difficult to pre-maintain and pre-install this supplemental light structure. The present disclosure provides the following technical solutions to solve the above technical problem.

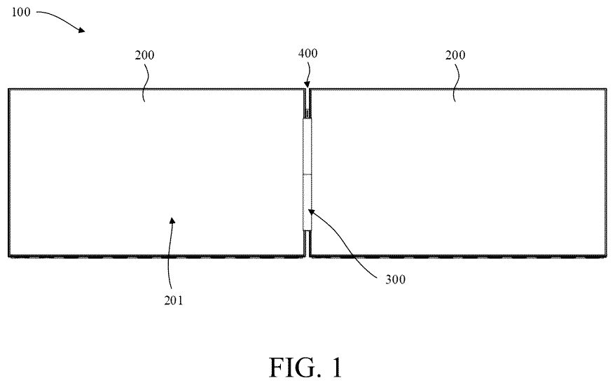

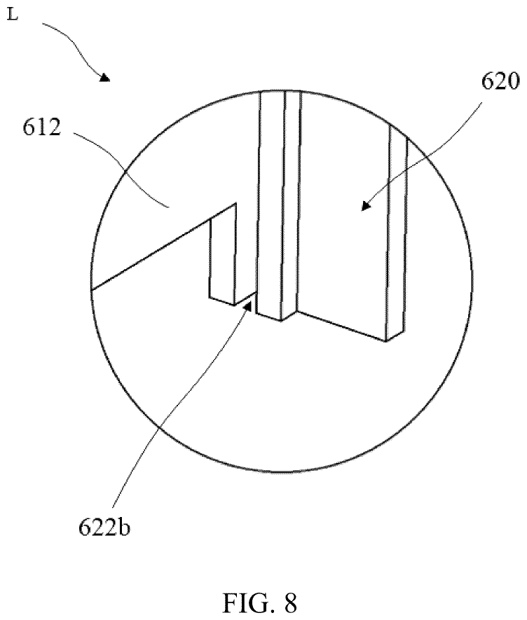

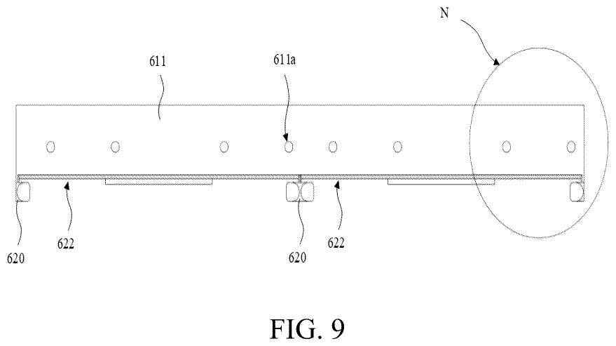

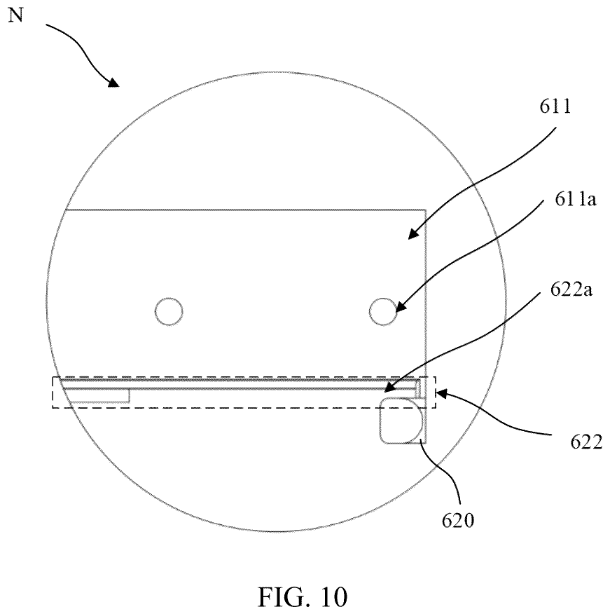

Referring to FIGS. 1 to 10, the present disclosure provides a display apparatus 100. The display apparatus 100 includes at least two display devices 200, a supplementary light assembly 300, and a transition bracket 60, and a splicing gap 400 is formed between two adjacent display devices 200. The display devices 200 may be LCD devices, Mini LED display devices, Micro LED display devices or other light emitting display devices.

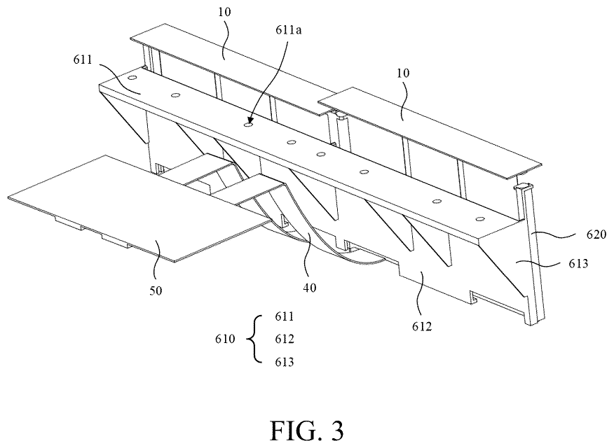

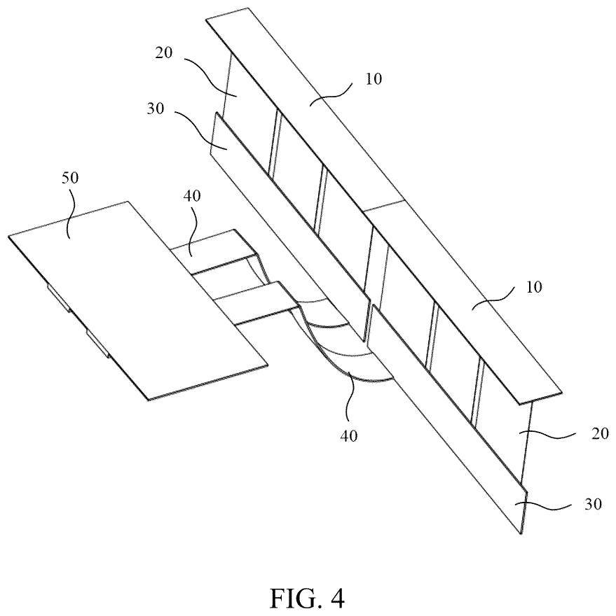

In the embodiments, referring to FIGS. 3 and 4, the supplementary light assembly 300 may include a light bar 10, a first transmission member 20, a transition board 30, and a second transmission member 40 which are connected.

In the embodiments, referring to FIGS. 3 and 4, the light bar 10 may be disposed on a light emitting side 201 of the two adjacent display devices 200, and the light bar 10 covers the splicing gap 400. The first transmission member 20 may be disposed within the splicing gap 400, a first terminal of the first transmission member 20 is electrically connected to a side of the light bar 10 away from the light emitting side 201, and a second terminal of the first transmission member 20 extends toward a backside 202 (the side opposite the light emitting side 201) of the display devices 200 and passes through the splicing gap 400. The transition board 30 may be disposed on a side of the first transmission member 20 away from the light bar 10, and the second terminal of the first transmission member 20 is electrically connected to a first terminal of the transition board 30. The second transmission member 40 may be disposed on the backside 202 of the two adjacent display devices 200, and a first terminal (end) of the second transmission member 40 is detachably connected to a second terminal of the transition board 30. The transition bracket 60 may be disposed on the backside 202 of the two adjacent display devices 200, and a portion of the transition bracket 60 extends into the splicing gap 400. The transition bracket 60 may be detachably connected to at least one of the two adjacent display devices 200, and the transition assembly 300 is detachably connected to the transition bracket 60.

In the present disclosure, the transition bracket 60 is disposed on the backside 202 of one of the two adjacent display devices 200, and the supplementary light assembly 300 is detachably connected to the transition bracket 60. In this manner, the installation of the light bar 10 and the transition board 30 is simplified while the separation design of the light bar and a driver in the supplemental light assembly 300 and the detachable connection between the second transmission member 40 and the transition board 30 are achieved, which is convenient for the maintenance of the overall supplemental light assembly 300.

It is to be noted that in the present disclosure, the light bar 10 is detachably connected to the first transmission member 20, the transition board 30 is detachably connected to the first transmission member 20 and the second transmission member 40 separately, and the supplementary light assembly 300 is detachably connected to the transition bracket 60. The components in the present disclosure are detachable, which facilitates the maintenance and installation of the components.

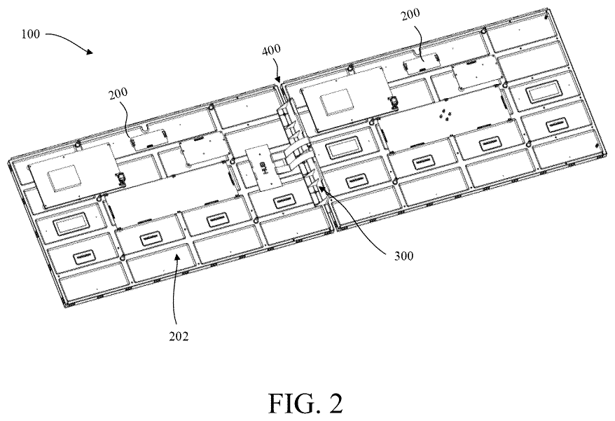

It is to be noted that the number of display devices 200 may be 2n, for example, the display apparatus 100 is configured in the 1×2 combination shown in FIG. 1, where one splicing gap 400 is formed between two adjacent display devices 200, and the supplementary light assembly 300 is used to eliminate the splicing gap 400 between the two adjacent display devices 200; alternatively, the display apparatus 100 is configured in the 2×2 combination of four display devices 200, and four splicing gaps 400 are formed between the four display devices 200, so one supplementary light assembly 300 is required to be provided within each of the four splicing gaps 400. The technical solutions of the present disclosure are described with the following embodiments of the display apparatus 100 configured in the 1×2 combination in FIGS. 1 and 2.

It is to be noted that in the present disclosure, two light bars 10 may be provided between two adjacent display devices 200, each light bar 10 is connected to three first transmission members 20, the three first transmission members 20 are connected to one transition board 30, the one transition board 30 is connected to one second transmission member 40, and then two second transmission members 40 are connected to the same controller 50. When the length of the splicing gap 400 is relatively large, three or more light bars 10 may be provided, and the number of light bars 10 is mainly determined according to the length of the splicing gap 400 and the length of the light bars 10 themselves. In the following embodiments, the technical solutions of the present disclosure are described using two light bars 10 as an example.

It is to be noted that light emitting devices in the light bars 10 may be Mini LEDs or Micro LEDs, the corresponding size of the LEDs may be set according to the size and resolution of the display apparatus 100, and the light emitting devices may be LED devices emitting red, green and blue light.

It is to be noted that the supplementary light assembly 300 further includes a controller 50, the controller 50 being a hub. The controller 50 may be fixed to the backside 202 of one of the two adjacent display devices 200, and second terminals of the second transmission members 40 are electrically connected to the controller 50.

It is to be noted that the first transmission members 20 may be printed circuit boards and the second transmission members 40 may be flexible flat cables. Each first transmission member 20 is usually formed by utilizing chemical etching to process the flexible copper clad laminate (FCCL) to obtain a printed circuit board which may be single-sided, double-sided, or multi-layered with different trace patterns. Each second transmission member 40 is usually formed by utilizing two layers of insulating foils at the top and bottom and a flat copper foil in the middle, which makes the finished product simpler and thicker.

The technical solutions of the present disclosure are described in conjunction with specific embodiments.

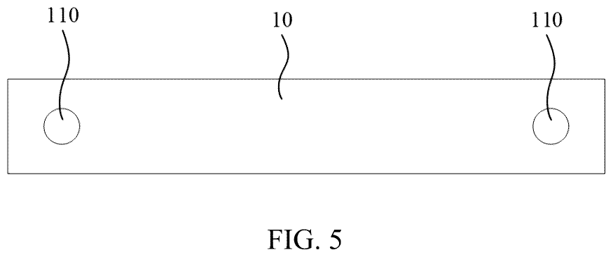

In the display apparatus 100 of the present disclosure, referring to FIG. 5, the supplementary light assembly 300 further includes at least two spacers 110 disposed on a side of each light bar 10 away from the light emitting side. The at least two spacers 110 are disposed on two sides of the light bar 10. The spacers 110 are detachably connected to the transition bracket 60, and the at least two spacers 110 are disposed in the splicing gap 400.

Referring to FIG. 5, the spacers 110 may be magnetic metal pads, which are mainly used to fix the light bar 10 on the transition bracket 60. To facilitate the removal of the light bar 10, a magnet member may be provided on the transition bracket 60 in the present embodiments to magnetically attract the light bar 10 to the transition bracket 60, which simplifies the installation of the light bar 10, and besides, the detachable connection between the light bar 10 and the transition bracket 60 allows for easy dismantling of the light bar 10 and convenient maintenance of the light bar 10. Moreover, to ensure a seamless fit of the light bar 10 with the surface of the display devices 200, the positions of the spacers 110 correspond to the splicing gap 400, i.e., when the light bar 10 fits the surface of the display devices 200, the spacers 110 may be fitted into the splicing gap 400.

In the embodiments, in order for the light bar 10 to eliminate the splicing gap 400 as much as possible, the width of the splicing gap 400 needs to be smaller than the width of the light bar 10 in the present disclosure, thereby realizing seamless splicing of the display devices 200.

Moreover, the spacing between the light emitting devices in the light bars 10 and light emitting devices, adjacent to the light emitting devices in the light bars 10, in the display device 200 needs to be close to or equal to the spacing between two adjacent light emitting devices in each display device 200, thereby realizing the spacing between two adjacent light emitting devices at any position of the display apparatus 100 to be equal. When there are multiple columns of light emitting devices provided in the light bars 10, the spacing between two adjacent light emitting devices in the light bars 10 needs to be close to or equal to the spacing between two adjacent light emitting devices in each display device 200, thereby realizing the spacing between two adjacent light emitting devices at any position of the display apparatus 100 to be equal, and satisfying the distribution uniformity of the light emitting devices.

In the embodiments, two spacers 110 may be provided on one light bar 10, and the spacers 110 may be fixedly connected to the back side of the light bar 10 by an adhesive layer such as 416 instantaneous adhesive or a solder material such as tin.

In the embodiments, referring to FIGS. 3 and 4, the first transmission members 20 and the transition boards 30 may be disposed in the same plane, the transition boards 30 and the light bars 10 are disposed to be perpendicular to each other, and the first transmission members 20 and the transition boards 30 are disposed separately from the adjacent display device 200.

In the structure of FIGS. 3 and 4, the first transmission members 20 and the transition boards 30 are disposed to be perpendicular to each other, first terminals of the first transmission members 20 are electrically connected to interfaces of the light bars 10, and second terminals of the first transmission members 20 are electrically connected to first terminals of the transition boards 30. In the embodiments, the first terminal of each transition board 30 is provided with three adapter interfaces, and each adapter interface is electrically connected to one first transmission member 20; the second terminal of each transition board 30 is provided with two adapter interfaces, and one second transmission member 40 may select one of the two adapter interfaces to cause the second transmission member 40 to be electrically connected to the selected adapter interface.

In the structure of FIGS. 3 and 4, in order for the second transmission circuit 40 board to make a connection, the second transmission members 40 are bent along their extension from the output terminals of the transition boards 30 to the connection terminals of the controller 50.

In the embodiments, the first transmission members 20 are detachably connected to the light bars 10 and the transition boards 30, and the second transmission members 40 are detachably connected to the transition boards 30 and the controller 50.

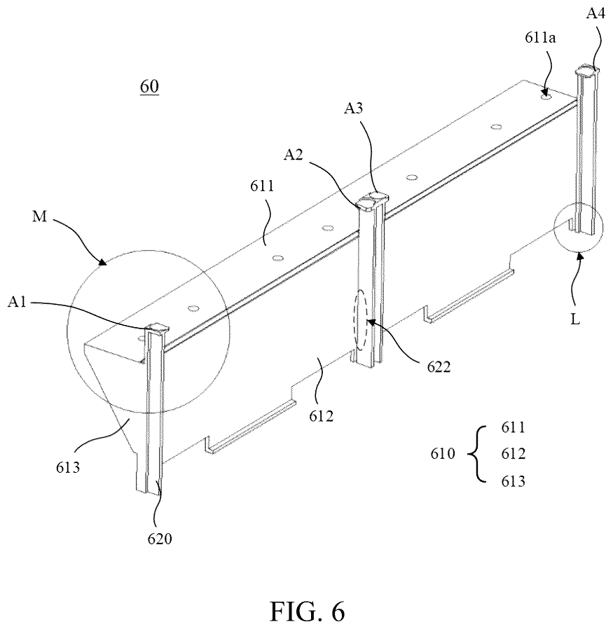

In the embodiments, referring to FIG. 6, the transition bracket 60 may include a transition body 610 and multiple fixing rods 620 disposed on a side of the transition body 610, and the light bars 10 and the transition boards 30 are detachably connected to the fixing rods 620.

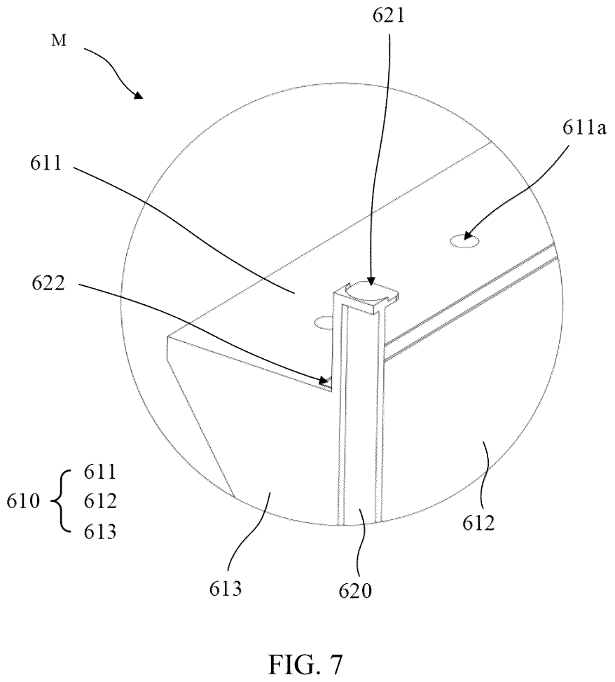

Referring to FIGS. 6 and 7, the transition body 610 may include a first body 611 and a second body 612 disposed to be perpendicular to each other, the first body 611 and the light bars 10 are disposed in parallel, and the orthogonal projection of the second body 612 on the display apparatus 100 is within the splicing gap 400. The first body 611 is provided with multiple mounting holes 611a, and the first body 611 is fixedly connected, through the multiple mounting holes 611a, to the surface of the display devices 200 on the backside 202.

In the embodiments, the surface of the display devices 200 on the backside 202 is provided with fixing holes (not shown) corresponding to the multiple mounting holes 611a, screws are provided within the mounting holes 611a and the fixing holes, and the first body 611 is fixedly connected, through the multiple screws, to the side of the display devices 200 away from the light emitting side of the display apparatus 100. Moreover, since the fixing rods 620 are mainly used to fix the light bars 10 and the transition boards 30 at the position of the splicing gap 400, the orthogonal projection of the second body 612 within the splicing gap 400 needs to be located within the splicing gap 400.

Referring to FIGS. 6 and 7, a side of each fixing rod 620 closer to the light bars 10 is provided with a groove 621 corresponding to one spacer 110, and the spacer 110 is fitted into the groove 621. Moreover, the magnetic member on the transition bracket 60 may be provided in the groove 621, and the spacer 110 and the magnetic member magnetically attract each other.

In the embodiments, the fixing rod 620 may extend from the bottom of the second body 612 toward the first body 611 and extend beyond the surface of the first body 611 and into the splicing gap 400 to be connected to the corresponding light bar 10.

For example, in FIGS. 6 to 10, four fixing plates are provided at the ends of the four fixing rods 620 closer to the light bars, the fixing plates are provided with grooves 621, the spacers 110 are fitted into the grooves 621, and one groove 621 corresponds to one spacer 110. The material of the fixing plates may be a magnet or a material having magnetic properties is provided on the surface of the fixing plates, and the spacers 110 are detachably connected to the fixing plates by magnetic force.

In the embodiments, referring to FIGS. 6 and 7, each groove 621 may also have an opening toward the adjacent fixing rod 620, i.e., the grooves 621 on two fixing plates corresponding to the same light bar 10 have opposing openings. For example, in FIG. 6, the groove 621 on the fixing plate A1 and the groove 621 on the fixing plate A2 have opposing openings, and the fixing plate A3 and the fixing plate A4 have opposing openings. Moreover, two adjacent fixing plates corresponding to different light bars 10 may be integrally provided; for example, the fixing plate A2 and the fixing plate A3 in FIG. 6 may be integrally provided.

In the present disclosure, the fixing plates with magnetic attraction are provided on the fixing rods 620, and the spacers 110 are fitted into the grooves 621 on the corresponding fixing plates, thereby realizing the detachable connection between the light bars 10 and the transition bracket 60. In this manner, the installation of the light bars 10 is simplified while the detachable connection between the light bars 10 and the transition bracket 60 facilitates the disassembly of the light bars 10, which is convenient for the maintenance of the light bars 10. Moreover, the grooves 621 on two adjacent fixing rods 620 have opposite openings, which can avoid shaking of the light bars 10.

In the display apparatus 100 of the present disclosure, referring to FIGS. 3, 6, and 7, the transition bracket 60 further includes multiple reinforcing ribs 613, a first side of the reinforcing ribs 613 is fixedly connected to the first body 611, and a second side of the reinforcing ribs 613 is fixedly connected to the second body 612. The reinforcing ribs 613 are mainly used to connect the first body 611 to the second body 612 and increase the strength of the transition bracket 60.

Referring to FIGS. 6 to 10, receiving cavities 622 are further provided between the second body 612 and the multiple fixing rods 620, a receiving inlet 622a is provided on a side of each receiving cavity 622 closer to the light bars 10, and a receiving outlet 622b is provided on a side of the receiving cavity 622 away from the light bars 10. The first transmission members 20 and the transition boards 30 enter into the receiving cavities 622 from respective receiving inlets, and the second terminal of each transition board 30 at a corresponding receiving outlet 622b is connected to the first terminal of the corresponding second transmission member 40.

In the embodiments, the second body 612 is of a sandwich design. When a transition board 30 is installed, the transition board 30 may enter a receiving cavity 622 through a receiving inlet 622a; two terminals of the transition board 30 can slide inside the receiving cavity 622 and nest inside the receiving cavity 622, and the sliding of the transition board 30 can drive corresponding first transmission members 20 to move inside the receiving cavity 622 so that the first transmission members 20 are fixed within the receiving cavity 622, and the second terminal of the transition board 30, at the position where a receiving outlet 622b is located, is connected to the first terminal of a corresponding second transmission member 40. Moreover, the transition board 30 may slide out of the slot 622 such that the transition board 30 and the first transmission members 20 are separated from the transition bracket 60.

In the embodiments, the number of receiving cavities 622 may be more than one, the number of receiving cavities 622 may be the same as the number of transition boards 30, and one transition board 30 may be disposed within one receiving cavity 622.

In the embodiments, the thickness of the transition board 30 is less than the width of the receiving cavity 622 in the direction from the first body 611 to the second body 612. To allow the transition board 30 to slide freely within the receiving cavity 622, the thickness of the transition board 30 needs to be less than the width of the receiving cavity 622 in the present disclosure, thereby preventing the transition board 30 in the receiving cavity 622 from interfering with the second body 612.

In the embodiments, to facilitate the smooth entry of the transition board 30 into the receiving cavity 622, a chamfer may be formed at the position where the first body 611 is connected to the second body 612 to increase the width of the receiving cavity 622 at the inlet position, i.e., in the present disclosure, chamfers may be provided at the receiving inlet position and at the receiving outlet position to increase the width of the receiving cavity 622 at the inlet position and the outlet position.

In the embodiments, the display apparatus may be an electronic display device such as a cell phone, a television, a laptop computer, and the like.

In the above embodiments, the description of each embodiment has its own focus, and parts of an embodiment that are not described in detail can be found in the relevant descriptions of other embodiments.

The above embodiments of the present disclosure provide a detailed description of the display apparatus, specific examples are used to explain the principles and embodiments of the present disclosure, and the above description of the embodiments is only used to help understand the technical solutions of the present disclosure and its core ideas. For a person skilled in the art, it is understood that it is still possible to modify the technical solutions recorded in the preceding embodiments, or to replace some technical features in the technical solutions with equivalent ones; and these modifications or replacements do not take the essence of the corresponding technical solutions out of the scope of the technical solutions of the embodiments of this disclosure.

1. A display apparatus, comprising:
at least two display devices, a splicing gap being formed between two adjacent display devices of the at least two display devices;
a transition bracket disposed on a backside of the two adjacent display devices, a portion of the transition bracket extending into the splicing gap, and the transition bracket being detachably connected to at least one of the two adjacent display devices; and
a supplementary light assembly detachably connected to the transition bracket;
wherein the supplementary light assembly comprises:
one or more light bars disposed on a light emitting side of the two adjacent display devices, the one or more light bars covering the splicing gap;
one or more first transmission members disposed within the splicing gap, a first terminal of each first transmission member being electrically connected to a side of a corresponding one of the one or more light bars away from the light emitting side, and a second terminal of the first transmission member extending toward the backside of the two adjacent display devices and passing through the splicing gap;
one or more transition boards each disposed on a side of a corresponding one or more of the one or more first transmission members away from the one or more light bars, a first terminal of the transition board being electrically connected to the second terminal of each of the corresponding one or more first transmission members; and
one or more second transmission members each disposed on the backside of the two adjacent display devices, a first terminal of the second transmission member being detachably connected to a second terminal of a corresponding one of the one or more transition boards.

2. The display apparatus according to claim 1, wherein the one or more first transmission members and the one or more transition boards are disposed in a same plane, and each transition board is disposed to be perpendicular to each light bar; and
wherein the one or more first transmission members and the one or more transition boards are disposed separately from the two adjacent display devices.

3. The display apparatus according to claim 1, wherein the supplementary light assembly further comprises at least two spacers disposed on the side of each light bar away from the light emitting side, the at least two spacers are disposed on two sides of a corresponding one of the one or more light bars respectively, and the at least two spacers are detachably connected to the transition bracket; and
wherein the at least two spacers are disposed in the splicing gap.

4. The display apparatus according to claim 3, wherein the transition bracket comprises a transition body and a plurality of fixing rods disposed on a side of the transition body, and the one or more light bars and the one or more transition boards are detachably connected to the plurality of fixing rods.

5. The display apparatus according to claim 4, wherein a plurality of grooves are provided on a side of the plurality of fixing rods closer to the one or more light bars, the plurality of grooves correspond to the at least two spacers, and the at least two spacers are fitted into the respective grooves.

6. The display apparatus according to claim 5, wherein the at least two spacers are magnetic metal pads; and
the transition bracket further comprises one or more magnetic members, each magnetic member is disposed in one of the plurality of grooves, and one of the at least two spacers and the magnetic member which correspond to the groove magnetically attract each other.

7. The display apparatus according to claim 5, wherein one fixing plate is provided at an end of one of the plurality of fixing rods closer to the one or more light bars, and the groove of the fixing rod is provided on the fixing plate.

8. The display apparatus according to claim 4, wherein the transition body comprises a first body and a second body disposed to be perpendicular to each other, the first body and the one or more light bars are disposed in parallel, and an orthogonal projection of the second body on the display apparatus is within the splicing gap.

9. The display apparatus according to claim 8, wherein the first body is provided with a plurality of mounting holes, and the first body is fixedly connected, through the plurality of mounting holes, to a surface of the two adjacent display devices on the backside.

10. The display apparatus according to claim 8, wherein one or more receiving cavities are further provided between the second body and the plurality of fixing rods, a receiving inlet is provided on a side of each receiving cavity closer to the one or more light bars, and a receiving outlet is provided on a side of the receiving cavity away from the one or more light bars; and
wherein each first transmission member and each transition board enter into a corresponding one of the one or more receiving cavities from the receiving inlet, and the second terminal of the transition board at the receiving outlet is connected to the first terminal of the corresponding second transmission member.

11. The display apparatus according to claim 10, wherein in a direction from the first body to the second body, a thickness of each transition board is less than a width of the corresponding receiving cavity containing the transition board.

12. The display apparatus according to claim 10, wherein a number of the one or more receiving cavities is equal to a number of the one or more transition boards.

13. The display apparatus according to claim 8, wherein a chamfer is formed at a position where the first body is connected to the second body.

14. The display apparatus according to claim 8, wherein the transition bracket further comprises a plurality of reinforcing ribs, a first side of each reinforcing rib is fixedly connected to the first body, and a second side of each reinforcing rib is fixedly connected to the second body.

15. The display apparatus according to claim 3, wherein the at least two spacers are fixedly connected to the corresponding light bar by an adhesive layer or a solder material.

16. The display apparatus according to claim 1, wherein a width of the splicing gap is smaller than a width of each of the one or more light bars.

17. The display apparatus according to claim 1, wherein the one or more first transmission members are each a printed circuit board, and the one or more second transmission members are each a flexible flat cable.

18. The display apparatus according to claim 1, wherein a spacing between light emitting devices in each light bar and light emitting devices, adjacent to the light emitting devices in the light bar, in each of the two adjacent display devices is equal to a spacing between two adjacent ones of the light emitting devices in each of the two adjacent display devices.

19. A display apparatus, comprising:
at least two display devices, a splicing gap being formed between two adjacent display devices of the at least two display devices;
a transition bracket disposed on a backside of the two adjacent display devices, a portion of the transition bracket extending into the splicing gap, and the transition bracket being detachably connected to at least one of the two adjacent display devices; and
a supplementary light assembly detachably connected to the transition bracket;
wherein the supplementary light assembly comprises:
one or more light bars disposed on a light emitting side of the two adjacent display devices, the one or more light bars covering the splicing gap;
one or more first transmission members disposed within the splicing gap, a first terminal of each first transmission member being electrically connected to a side of a corresponding one of the one or more light bars away from the light emitting side, and a second terminal of the first transmission member extending toward the backside of the two adjacent display devices and passing through the splicing gap;
one or more transition boards each disposed on a side of a corresponding one or more of the one or more first transmission members away from the one or more light bars, a first terminal of the transition board being electrically connected to the second terminal of each of the corresponding one or more first transmission members;
one or more second transmission members each disposed on the backside of the two adjacent display devices, a first terminal of the second transmission member being detachably connected to a second terminal of a corresponding one of the one or more transition boards; and
a controller fixed to the backside of one of the two adjacent display devices, a second terminal of the second transmission member being electrically connected to the controller.

20. The display apparatus according to claim 19, wherein the transition bracket comprises a transition body and a plurality of fixing rods disposed on a side of the transition body, the transition body comprises a first body and a second body disposed to be perpendicular to each other, the first body and the one or more light bars are disposed in parallel, and an orthogonal projection of the second body on the display apparatus is within the splicing gap;
wherein one or more receiving cavities are further provided between the second body and the plurality of fixing rods, a receiving inlet is provided on a side of each receiving cavity closer to the one or more light bars, and a receiving outlet is provided on a side of the receiving cavity away from the one or more light bars; and
wherein each first transmission member and each transition board enter into a corresponding one of the one or more receiving cavities from the receiving inlet, and the second terminal of the transition board at the receiving outlet is connected to the first terminal of the corresponding second transmission member.
